(19) United States
(12) Patent Application Publication
(10) Pub. No.: US 2025/0261415 A1
(43) Pub. Date: Aug. 14, 2025

(54) INTEGRATED CIRCUIT DEVICE

(71) Applicant: Samsung Electronics Co., Ltd., Suwon-si (KR)

(72) Inventors: Soojung Choi, Suwon-si (KR); Sangkoo Kang, Suwon-si (KR); Chaeho Na, Suwon-si, Gyeonggi-do (KR)

(21) Appl. No.: 18/813,545

(22) Filed: Aug. 23, 2024

(30) Foreign Application Priority Data
Feb. 14, 2024 (KR) 10-2024-0021269

(51) Int. Cl. H01L 29/06; H01L 21/8234; H01L 27/088; H01L 29/08; H01L 29/423; H01L 29/66; H01L 29/775; H01L 29/786

(52) U.S. Cl. CPC H10D 62/121; H10D 30/014; H10D 30/43; H10D 30/6735; H10D 30/6757; H10D 62/115; H10D 62/151; H10D 64/021; H10D 84/0144; H10D 84/038; H10D 84/83

(57) ABSTRACT

An integrated circuit device includes a pair of fin-type active regions that extend in a first direction and are on a substrate, a gate line that is on the pair of fin-type active regions and extends in a second direction, and a field insulating structure that is between the substrate and the gate line, where the field insulating structure includes: a first buried insulating film that contacts the sidewall of each of the pair of fin-type active regions, an insulating liner that is between the pair of fin-type active regions and at least partially overlaps the first buried insulating film in a third direction, and a second buried insulating film that is between the pair of fin-type active regions and at least partially overlaps the insulating liner in the third direction, where the second buried insulating film includes a nitride film.

### CROSS-REFERENCE TO RELATED APPLICATION

This application is based on and claims priority under 35 U.S.C. § 119 to Korean Patent Application No. 10-2024-0021269, filed on Feb. 14, 2024, in the Korean Intellectual Property Office, the disclosure of which is incorporated by reference herein in its entirety.

### TECHNICAL FIELD

The present disclosure relates to an integrated circuit device, and more particularly, to an integrated circuit device including a field-effect transistor.

### BACKGROUND

Along with the rapid down-scaling of integrated circuit devices, it is desirable for integrated circuit devices to secure the high operation speeds and the accuracy in operations as well. Therefore, various researches are being conducted to provide integrated circuit devices that have structures capable of providing optimum performance and improving the reliability thereof.

### SUMMARY

The present disclosure provides an integrated circuit device that has a structure capable of improving the performance of a transistor and reducing power consumption by reducing parasitic capacitance between adjacent conductive regions.

According to an aspect of the present disclosure, there is provided an integrated circuit device including a pair of fin-type active regions that extend in a first direction and are on a substrate, a gate line that is on the pair of fin-type active regions and extends in a second direction that intersects the first direction, and a field insulating structure that is between the substrate and the gate line and at least partially overlaps a sidewall of each of the pair of fin-type active regions in the second direction, where the field insulating structure includes: a first buried insulating film that contacts the sidewall of each of the pair of fin-type active regions, an insulating liner that is between the pair of fin-type active regions and at least partially overlaps the first buried insulating film in a third direction that is perpendicular to the first direction and the second direction, and a second buried insulating film that is between the pair of fin-type active regions and at least partially overlaps the insulating liner in the third direction, where the second buried insulating film is spaced apart from the first buried insulating film in the third direction, where the insulating liner is between the second buried insulating film and the first buried insulating film, and where the second buried insulating film includes a nitride film.

According to another aspect of the present disclosure, there is provided an integrated circuit device including a fin-type active region that extends in a first direction and is on a substrate, a nanosheet stack spaced apart from a fin top surface of the fin-type active region in a second direction that is perpendicular to the first direction, where the nanosheet stack faces the fin top surface and includes at least one nanosheet that is separated from the substrate in the second direction by a first distance that is different from a second distance between the fin top surface and the substrate, a gate line that is on the fin-type active region, at least partially surrounds the at least one nanosheet, and extends in a third direction that intersects the first direction, and a field insulating structure that is between the substrate and the gate line and at least partially overlaps a sidewall of the fin-type active region in the third direction, where the field insulating structure includes: a first buried insulating film that contacts the sidewall of the fin-type active region, an insulating liner that at least partially overlaps an upper surface of the first buried insulating film in the second direction, and a second buried insulating film that at least partially overlaps the insulating liner in the second direction, is spaced apart from the first buried insulating film in the second direction, where the insulating liner is between the second buried insulating film and the first buried insulating film, and where the second buried insulating film includes a nitride film.

According to another aspect of the present disclosure, there is provided an integrated circuit device including a pair of fin-type active regions that extend in a first direction and are on a substrate, a pair of nanosheet stacks that are respectively on the pair of fin-type active regions and each include at least one nanosheet, a gate line that is on the pair of fin-type active regions, at least partially surrounds the at least one nanosheet of each of the pair of nanosheet stacks, and extends in a second direction that intersects the first direction, a pair of source/drain regions respectively on the pair of fin-type active regions, and a field insulating structure that is between the pair of fin-type active regions and includes a first portion between the substrate and the gate line and a second portion between the pair of source/drain regions, where the field insulating structure includes: a first buried insulating film that contacts a sidewall of each of the pair of fin-type active regions, an insulating liner that at least partially overlaps an upper surface of the first buried insulating film in a third direction by a constant thickness, where the third direction is perpendicular to the first direction and the second direction, and a second buried insulating film that at least partially overlaps the insulating liner and is spaced apart from the first buried insulating film in the third direction, where the insulating liner is between the first buried insulating film and the second buried insulating film, where the second buried insulating film includes a varying thickness in the third direction and the second direction, where the first buried insulating film and the insulating liner respectively include silicon oxide films having different densities, and where the second buried insulating film of the field insulating structure includes a silicon nitride (SiN) film, a silicon oxynitride (SiON) film, a silicon oxycarbonitride (SiOCN) film, or a combination thereof.

### BRIEF DESCRIPTION OF THE DRAWINGS

Embodiments will be more clearly understood from the following detailed description taken in conjunction with the accompanying drawings in which:

FIG. 1 is a planar layout diagram illustrating an integrated circuit device according to some embodiments;

FIG. 2 is a cross-sectional view of the integrated circuit device of FIG. 1, taken along a line X1-X1′ of FIG. 1;

FIG. 3 is a cross-sectional view of the integrated circuit device of FIG. 1, taken along a line Y1-Y1′ of FIG. 1;

FIG. 4 is a cross-sectional view of the integrated circuit device of FIG. 1, taken along a line Y2-Y2′ of FIG. 1;

FIG. 5 is an enlarged cross-sectional view of a region EX1 of FIG. 3;

FIG. 6 is a cross-sectional view illustrating an integrated circuit device according to some embodiments;

FIG. 7 is a cross-sectional view illustrating an integrated circuit device according to some embodiments;

FIG. 8 is a cross-sectional view illustrating an integrated circuit device according to some embodiments;

FIGS. 9A to 21B are cross-sectional views illustrating a sequence of processes of a method of fabricating an integrated circuit device, according to some embodiments, and in particular, FIGS. 9A, 15A, 16, 17, 18, 19A, 20A, and 21A are cross-sectional views illustrating some components in a region corresponding to the cross-section taken along the line X1-X1′ of FIG. 1, according to the sequence of processes, and FIGS. 9B, 10, 11, 12, 13, 15B, 19B, 20B, and 21B are cross-sectional views illustrating some components in a region corresponding to the cross-section taken along the line Y1-Y1′ of FIG. 1, according to the sequence of processes; and

FIG. 22 is a cross-sectional view illustrating a method of fabricating an integrated circuit device according to some embodiments.

### DETAILED DESCRIPTION

To clarify the present disclosure, parts that are not connected with the description will be omitted, and the same elements or equivalents are referred to by the same reference numerals throughout the specification. In the drawings, the thickness of layers, films, panels, regions, etc., are exaggerated for clarity. Further, since sizes and thicknesses of constituent members shown in the accompanying drawings are arbitrarily given for better understanding and ease of description, the present disclosure is not limited to the illustrated sizes and thicknesses.

It will be understood that when an element such as a layer, film, region, or substrate is referred to as being “on” another element, it can be directly on the other element or intervening elements may also be present. In contrast, when an element is referred to as being “directly on” another element, there are no intervening elements present. Further, spatially relative terms, such as “beneath,” “below,” “lower,” “above,” “upper,” and the like, may be used herein for ease of description to describe one element's or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” can encompass both an orientation of above and below. The device may be otherwise oriented (rotated 90 degrees or at other orientations), and the spatially relative descriptors used herein may be interpreted accordingly.

In addition, unless explicitly described to the contrary, the word “comprises”, and variations such as “comprises” or “comprising”, will be understood to imply the inclusion of stated elements but not the exclusion of any other elements. As used herein, the singular forms “a,” “an” and “the” are intended to include the plural forms as well, unless the context clearly indicates otherwise. The term “and/or” includes any and all combinations of one or more of the associated listed items. The term “connected” may be used herein to refer to a physical and/or electrical connection and may refer to a direct or indirect physical and/or electrical connection. Components or layers described with reference to “overlap” in a particular direction may be at least partially obstructed by one another when viewed along a line extending in the particular direction or in a plane perpendicular to the particular direction.

Hereinafter, embodiments of the present disclosure will be described in detail with reference to the accompanying drawings. Like components are denoted by like reference numerals throughout the specification, and repeated descriptions thereof are omitted.

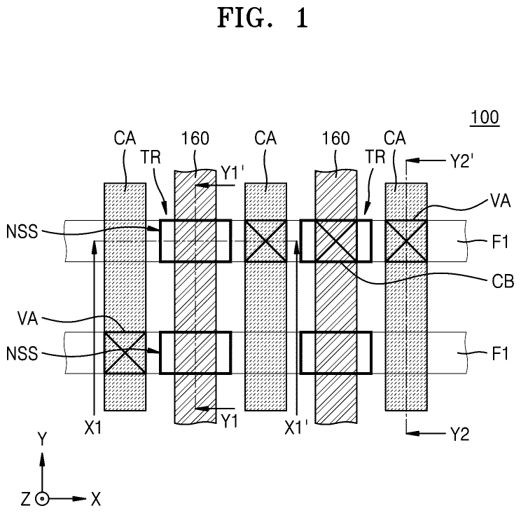

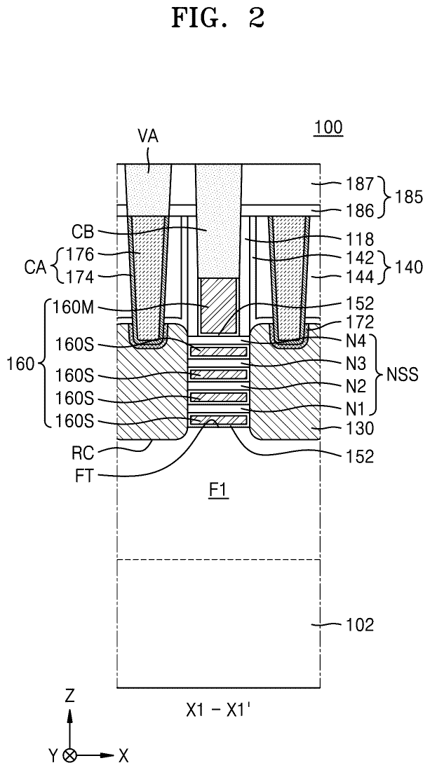

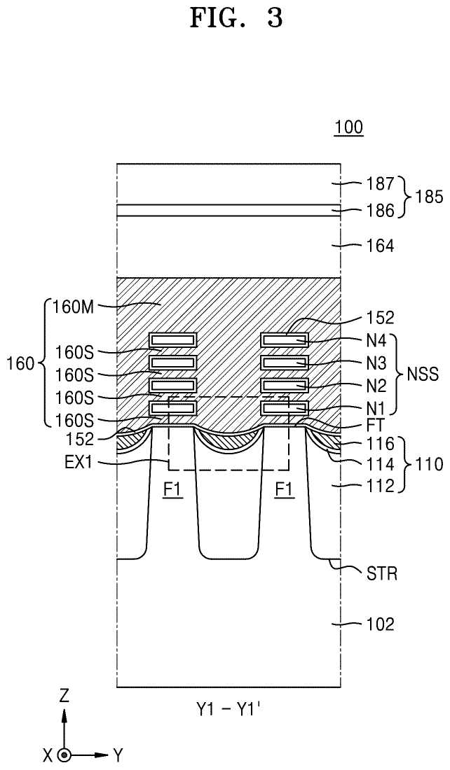

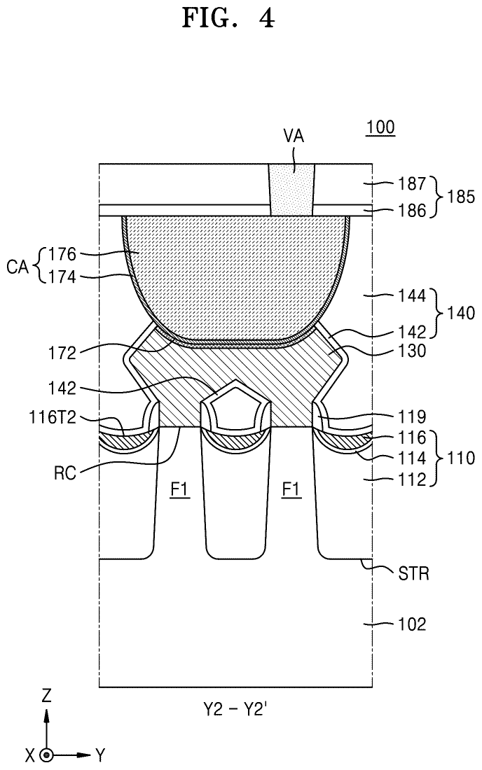

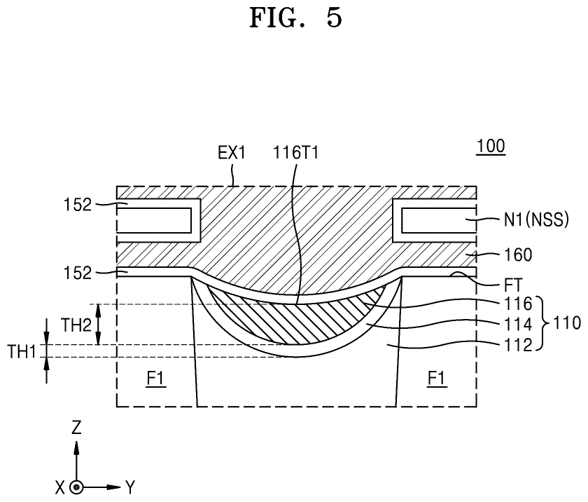

FIG. 1 is a planar layout diagram illustrating an integrated circuit device 100 according to some embodiments. FIG. 2 is a cross-sectional view of the integrated circuit device 100, taken along a line X1-X1′ of FIG. 1. FIG. 3 is a cross-sectional view of the integrated circuit device 100, taken along a line Y1-Y1′ of FIG. 1. FIG. 4 is a cross-sectional view of the integrated circuit device 100, taken along a line Y2-Y2′ of FIG. 1. FIG. 5 is an enlarged cross-sectional view of a region EX1 of FIG. 3. The integrated circuit device 100 including a field-effect transistor TR, which has a gate-all-around structure including a nanowire or nanosheet-shaped active region and a gate surrounding the active region, is described with reference to FIGS. 1 and 5.

Referring to FIGS. 1 to 5, the integrated circuit device 100 may include a plurality of fin-type active regions F1, which protrude or extend from a substrate 102 and extend lengthwise in a first horizontal direction (an X direction), and a plurality of nanosheet stacks NSS, which are located upwardly apart from each of the plurality of fin-type active regions F1 in a vertical direction (a Z direction) to face a fin top surface FT of each of the plurality of fin-type active regions F1. As used herein, the term “nanosheet” refers to a conductive structure having a cross-section that is substantially perpendicular to a current-flowing direction. The nanosheet may also be understood as including a nanowire. The substrate 102 may include a semiconductor, such as Si or Ge, or a compound semiconductor, such as SiGe, SiC, GaAs, InAs, InGaAs, or InP. As used herein, each of the terms “SiGe”, “SiC”, “GaAs”, “InAs”, “InGaAs”, and “InP” refers to a material including elements contained in each term and is not a chemical formula representing a stoichiometric relationship. The substrate 102 may include a conductive region, for example, an impurity-doped well or an impurity-doped structure.

A trench STR may be formed in the substrate 102 to define the plurality of fin-type active regions F1. The trench STR between a pair of fin-type active regions F1 adjacent to each other in a second horizontal direction (a Y direction) from among the plurality of fin-type active regions F1 may be filled with or include a field insulating structure 110.

The field insulating structure 110 may include a first buried insulating film 112 contacting a sidewall of each of the pair of fin-type active regions F1 adjacent to the field insulating structure 110 in the second horizontal direction (the Y direction) that intersects with the first horizontal direction (the X direction), an insulating liner 114 arranged between the pair of fin-type active regions F1 to cover or overlap the upper surface of the first buried insulating film 112 in the vertical direction (the Z direction), and a second buried insulating film 116 arranged between the pair of fin-type active regions F1 to cover or overlap the upper surface of the insulating liner 114 in the vertical direction (the Z direction). The second buried insulating film 116 may be spaced apart from the field insulating structure 110 in the vertical direction (the Z direction) with the insulating liner 114 therebetween.

In the field insulating structure 110, each of the first buried insulating film 112 and the insulating liner 114 may include a silicon oxide film, and the second buried insulating film 116 may include a nitride film.

In some embodiments, the density of the silicon oxide film constituting the first buried insulating film 112 may be different from the density of the silicon oxide film constituting the insulating liner 114. For example, the density of the silicon oxide film constituting the insulating liner 114 may be greater than the density of the silicon oxide film constituting the first buried insulating film 112. In this case, the difference in density between the first buried insulating film 112 and the insulating liner 114 may result from the difference between respective formation processes of the first buried insulating film 112 and the insulating liner 114. For example, the first buried insulating film 112 may include a silicon oxide film formed by a chemical vapor deposition (CVD) process, and the insulating liner 114 may include a silicon oxide film formed by an atomic layer deposition (ALD) process. Here, the density of the insulating liner 114 formed by the ALD process may be greater than the density of the first buried insulating film 112 formed by the CVD process. The second buried insulating film 116 may include a silicon nitride (SiN) film, a silicon oxynitride (SiON) film, a silicon oxycarbonitride (SiOCN) film, or a combination thereof. For example, the second buried insulating film 116 may include a silicon nitride (SiN) film.

A plurality of gate lines 160 may be arranged over or on the plurality of fin-type active regions F1. Each of the plurality of gate lines 160 may extend lengthwise in the second horizontal direction (the Y direction) intersecting with the first horizontal direction (the X direction). In intersection areas between the plurality of fin-type active regions F1 and the plurality of gate lines 160, a plurality of nanosheet stacks NSS may be arranged over the fin top surface FT of each of the plurality of fin-type active regions F1. Each of the plurality of nanosheet stacks NSS may include at least one nanosheet. As shown in FIGS. 2 and 3, each of the plurality of nanosheet stacks NSS may include a first nanosheet N1 (e.g., a lowermost nanosheet), a second nanosheet N2, a third nanosheet N3, and a fourth nanosheet N4, which overlap each other in the vertical direction (the Z direction), over the fin-type active region F1. Each of the first nanosheet N1, the second nanosheet N2, the third nanosheet N3, and the fourth nanosheet N4 of a nanosheet stack NSS may have a channel region. In some embodiments, each of the first nanosheet N1, the second nanosheet N2, the third nanosheet N3, and the fourth nanosheet N4 of the nanosheet stack NSS may include a Si layer, a SiGe layer, or a combination thereof.

The first nanosheet N1, the second nanosheet N2, the third nanosheet N3, and the fourth nanosheet N4 may respectively have different vertical distances (Z-direction distances) from the fin top surface FT of the fin-type active region F1. Each of the plurality of gate lines 160 may at least partially surround the first nanosheet N1, the second nanosheet N2, the third nanosheet N3, and the fourth nanosheet N4, which overlap each other in the vertical direction (the Z direction) and are included in the nanosheet stack NSS.

Although FIG. 1 illustrates an example in which the nanosheet stack NSS has a planar shape of an approximate quadrangle, the present disclosure is not limited thereto. The nanosheet stack NSS may have various planar shapes depending on the planar shape of each of the fin-type active region F1 and the gate line 160. The present example illustrates a configuration in which a plurality of gate lines 160 are arranged over or on one fin-type active region F1, and in which a plurality of nanosheet stacks NSS are arranged in a line in the first horizontal direction (the X direction) over or on one fin-type active region F1. However, the respective numbers of nanosheet stacks NSS and gate lines 160, which are arranged over or on one fin-type active region F1, are not particularly limited.

Each of the first nanosheet N1, the second nanosheet N2, the third nanosheet N3, and the fourth nanosheet N4 of the nanosheet stack NSS may function as a channel region. In some embodiments, each of the first nanosheet N1, the second nanosheet N2, the third nanosheet N3, and the fourth nanosheet N4 may have, but is not limited to, a thickness selected from a range of about 4 nm to about 6 nm. Here, the thickness of each of the first nanosheet N1, the second nanosheet N2, the third nanosheet N3, and the fourth nanosheet N4 refers to a size in the vertical direction (the Z direction). In some embodiments, the first nanosheet N1, the second nanosheet N2, the third nanosheet N3, and the fourth nanosheet N4 may have substantially the same thickness in the vertical direction (the Z direction). In some embodiments, at least some of the first nanosheet N1, the second nanosheet N2, the third nanosheet N3, and the fourth nanosheet N4 may respectively have different thicknesses in the vertical direction (the Z direction).

As shown in FIG. 2, the first nanosheet N1, the second nanosheet N2, the third nanosheet N3, and the fourth nanosheet N4, which are included one nanosheet stack NSS, may have equal or similar sizes to each other in the first horizontal direction (the X direction). In some embodiments, unlike the example shown in FIG. 2, at least some of the first nanosheet N1, the second nanosheet N2, the third nanosheet N3, and the fourth nanosheet N4, which are included one nanosheet stack NSS, may respectively have different sizes in the first horizontal direction (the X direction).

Although FIGS. 2 and 3 illustrate an example in which each of the plurality of nanosheet stacks NSS includes four nanosheets including the first nanosheet N1, the second nanosheet N2, the third nanosheet N3, and the fourth nanosheet N4, the present disclosure is not limited thereto. For example, the nanosheet stack NSS may include at least one nanosheet, and the number of nanosheets constituting the nanosheet stack NSS is not particularly limited.

As shown in FIGS. 2 and 3, each of the plurality of gate lines 160 may include a main gate portion 160M and a plurality of sub-gate portions 160S. The main gate portion 160M may extend lengthwise in the second horizontal direction (the Y direction) to cover or overlap the upper surface of the nanosheet stack NSS in the vertical direction (the Z direction). The plurality of sub-gate portions 160S may be integrally connected to the main gate portion 160M and may be respectively arranged one-by-one between the first nanosheet N1, the second nanosheet N2, the third nanosheet N3, and the fourth nanosheet N4 and between the first nanosheet N1 and the fin top surface FT of the fin-type active region F1. In the vertical direction (the Z direction), the thickness of each of the plurality of sub-gate portions 160S may be less than the thickness of the main gate portion 160M.

Each of the plurality of gate lines 160 may include a metal, a metal nitride, a metal carbide, or a combination thereof. The metal may be selected from Mo, Ru, Cu, and W. The metal nitride may be selected from TiN, TaN, TiAlN, and a combination thereof. The metal carbide may include TiAlC. However, a material constituting each of the plurality of gate lines 160 is not limited to the examples set forth above.

The field insulating structure 110 may be arranged between the substrate 102 and the gate line 160 in the vertical direction (the Z direction). The field insulating structure 110 may cover or overlap a sidewall of each of a pair of fin-type active regions F1 respectively adjacent to both sides of the field insulating structure 110 in the second horizontal direction (the Y direction). The first buried insulating film 112 of the field insulating structure 110 may be in contact with the sidewall of each of the pair of fin-type active regions F1 respectively adjacent to both sides of the first buried insulating film 112 in the second horizontal direction (the Y direction). The second buried insulating film 116 of the field insulating structure 110 may be spaced apart from, in the second horizontal direction (the Y direction), the sidewall of each of the pair of fin-type active regions F1 respectively adjacent to both sides of the second buried insulating film 116 in the second horizontal direction (the Y direction). In the second horizontal direction (the Y direction), the insulating liner 114 may be closer to the fin-type active region F1 than the second buried insulating film 116. The insulating liner 114 may include a portion contacting the fin-type active region F1.

In the field insulating structure 110, the insulating liner 114 may cover or overlap the lower surface in the vertical direction (the Z direction), which faces the substrate 102, of the second buried insulating film 116 by a constant thickness TH1. In the field insulating structure 110, a thickness TH2 of the second buried insulating film 116 in the vertical direction (the Z direction) may vary in the second horizontal direction (the Y direction). The thickness TH2 of the second buried insulating film 116 in the vertical direction (the Z direction) may gradually increase toward the center between the pair of fin-type active regions F1 respectively on both sides of the second buried insulating film 116 in the second horizontal direction (the Y direction), and may gradually decrease toward the fin-type active region F1 adjacent to the second buried insulating film 116.

As shown in FIG. 5, in the field insulating structure 110, the thickness TH2 of the second buried insulating film 116 in the vertical direction (the Z direction) may be greater than the thickness TH1 of the insulating liner 114 in the vertical direction (the Z direction). In some embodiments, the maximum thickness of the insulating liner 114 in the vertical direction (the Z direction) may be about 1 nm to about 2 nm and the maximum thickness of the second buried insulating film 116 in the vertical direction (the Z direction) may be about 4 nm to about 10 nm, but the present disclosure is not limited thereto.

In the vertical direction (the Z direction), the farthest portion of the second buried insulating film 116 of the field insulating structure 110 from the substrate 102 may be closer to the substrate 102 than the closest portion of the plurality of nanosheets of the nanosheet stack NSS to the substrate 102, that is, than the lower surface of the first nanosheet N1, which faces the fin top surface FT of the fin-type active region F1.

A gate dielectric film 152 may be arranged between the nanosheet stack NSS and the gate line 160. In some embodiments, the gate dielectric film 152 may include a stack structure of an interface dielectric film and a high-k film. The interface dielectric film may include a low-k material film having a dielectric constant of about 9 or less, for example, a silicon oxide film, a silicon oxynitride film, or a combination thereof. In some embodiments, the interface dielectric film may be omitted. The high-k film may include a material having a dielectric constant that is greater than that of a silicon oxide film. For example, the high-k film may have a dielectric constant of about 10 to about 25. The high-k film may include, but is not limited to, hafnium oxide.

The gate dielectric film 152 may be in contact with a surface of each of the plurality of fin-type active regions F1 and a surface of each of the first nanosheet N1, the second nanosheet N2, the third nanosheet N3, and the fourth nanosheet N4, which are included in each of the plurality of nanosheet stacks NSS, and may surround each of the plurality of gate lines 160. The gate dielectric film 152 may be in contact with the lower surface and both sidewalls of each of the plurality of gate lines 160.

As shown in FIGS. 3 to 5, in the second horizontal direction (the Y direction), the second buried insulating film 116 of the field insulating structure 110 may be spaced apart from each of the pair of fin-type active regions F1 respectively on both sides of the field insulating structure 110. The second buried insulating film 116 of the field insulating structure 110 may have an upper surface 116T1 contacting the gate dielectric film 152. Herein, the upper surface 116T1, which contacts the gate dielectric film 152, of the second buried insulating film 116, in the upper surface of the second buried insulating film 116, may be referred to as a first upper surface.

In the second buried insulating film 116 of the field insulating structure 110, the upper surface 116T1 contacting the gate dielectric film 152 may have a concave shape toward or relative to the gate line 160. In the second buried insulating film 116 of the field insulating structure 110, the lower surface contacting the insulating liner 114 may have a convex shape toward or relative to the substrate 102.

As shown in FIG. 3, the upper surface of each gate line 160 may be covered or overlapped by a capping insulating pattern 164 in the vertical direction (Z direction). The capping insulating pattern 164 may include a silicon nitride film.

Both sidewalls of each of the gate line 160 and the capping insulating pattern 164 in the second horizontal direction (the Y direction) may be respectively covered or overlapped by a pair of first insulating spacers 118. A plurality of first insulating spacers 118 in the integrated circuit device 100 may each extend lengthwise in the second horizontal direction (the Y direction) on the nanosheet stack NSS and the field insulating structure 110, together with the gate line 160. The first insulating spacer 118 may be arranged on the upper surface of each of the plurality of nanosheet stacks NSS and cover or overlap both sidewalls of the main gate portion 160M in the first horizontal direction (X direction). The first insulating spacer 118 may be spaced apart from the gate line 160 with the gate dielectric film 152 therebetween. The first insulating spacer 118 may include silicon nitride, silicon oxide, SiCN, SiBN, SiON, SiOCN, SiBCN, SiOC, or a combination thereof. As used herein, each of the terms “SiCN”, “SiBN”, “SiON”, “SiOCN”, “SiBCN”, and “SiOC” refers to a material including elements contained in each term and is not a chemical formula representing a stoichiometric relationship.

The pair of first insulating spacers 118 respectively covering or overlapping both sidewalls of the gate line 160 may extend lengthwise in the second horizontal direction (the Y direction) to define a space accommodating the gate line 160 and the capping insulating pattern 164. In the space defined by the pair of first insulating spacers 118, the gate line 160 may cover or overlap the fin-type active region F1 and the nanosheet stack NSS and extend lengthwise in the second horizontal direction (the Y direction). In the space defined by the pair of first insulating spacers 118, the gate dielectric film 152 may be in contact with the surface of the fin-type active region F1 and the surface of each of the first nanosheet N1, the second nanosheet N2, the third nanosheet N3, and the fourth nanosheet N4 of the nanosheet stack NSS and may be in contact with the lower surface and both sidewalls of the gate line 160.

As shown in FIGS. 2 and 4, a plurality of recesses RC may be formed in the fin-type active region F1. A vertical level of the lowermost surface of each of the plurality of recesses RC may be lower than a vertical level of the fin top surface FT of the fin-type active region F1. As used herein, the term “vertical level” refers to a distance in the vertical direction (the Z direction or the −Z direction) from the main surface of the substrate 102.

A plurality of source/drain regions 130 may be respectively arranged in the plurality of recesses RC. Each of the plurality of source/drain regions 130 may be arranged adjacent to at least one gate line 160 selected from the plurality of gate lines 160. Each of the plurality of source/drain regions 130 may have surfaces facing the first nanosheet N1, the second nanosheet N2, the third nanosheet N3, and the fourth nanosheet N4, which are included in the nanosheet stack NSS adjacent thereto. Each of the plurality of source/drain regions 130 may have surfaces contacting the first nanosheet N1, the second nanosheet N2, the third nanosheet N3, and the fourth nanosheet N4, which are included in the nanosheet stack NSS adjacent thereto.

Each of the plurality of source/drain regions 130 may include an epitaxially grown semiconductor layer. In some embodiments, each of the plurality of source/drain regions 130 may include an epitaxially grown Si layer, an epitaxially grown SiC layer, or a plurality of SiGe layers that are epitaxially grown. When the source/drain region 130 constitutes an NMOS transistor, the source/drain region 130 may include a Si layer doped with an n-type dopant or a SiC layer doped with an n-type dopant. The n-type dopant may be selected from phosphorus (P), arsenic (As), and antimony (Sb). When the source/drain region 130 constitutes a PMOS transistor, the source/drain region 130 may include a SiGe layer doped with a p-type dopant. The p-type dopant may be selected from boron (B) and gallium (Ga).

As shown in FIG. 2, both sidewalls of each of the plurality of sub-gate portions 160S of the gate line 160 may each be spaced apart from the source/drain region 130 with the gate dielectric film 152 therebetween. The gate dielectric film 152 may be arranged between the sub-gate portion 160S of the gate line 160 and each of the first nanosheet N1, the second nanosheet N2, the third nanosheet N3, and the fourth nanosheet N4 and between the sub-gate portion 160S of the gate line 160 and the source/drain region 130.

In the intersection areas between the plurality of fin-type active regions F1 and the plurality of gate lines 160, the plurality of nanosheet stacks NSS may be arranged over the fin top surface FT of each of the plurality of fin-type active regions F1, and a plurality of field-effect transistors TR may be respectively formed on the substrate 102 in the intersection areas between the plurality of fin-type active regions F1 and the plurality of gate lines 160.

A metal silicide film 172 may be formed on the upper surface of each of the plurality of source/drain regions 130. The metal silicide film 172 may include a metal including Ti, W, Ru, Nb, Mo, Hf, Ni, Co, Pt, Yb, Tb, Dy, Er, or Pd. For example, the metal silicide film 172 may include, but is not limited to, titanium silicide.

An insulating liner 142 and an inter-gate dielectric 144 may be arranged in the stated order on the plurality of source/drain regions 130 and a plurality of metal silicide films 172. The insulating liner 142 and the inter-gate dielectric 144 may constitute an inter-gate insulating structure 140. The first insulating spacer 118 and the plurality of source/drain regions 130 may be covered or overlapped by the insulating liner 142 in the second horizontal direction (Y direction). In some embodiments, the insulating liner 142 may include, but is not limited to, silicon nitride (SiN), SiCN, SiBN, SiON, SiOCN, SiBCN, or a combination thereof. The inter-gate dielectric 144 may include, but is not limited to, a silicon oxide film. In some embodiments, the insulating liner 142 may be omitted. When the insulating liner 142 is omitted, the inter-gate dielectric 144 may be in contact with the plurality of source/drain regions 130.

As shown in FIG. 4, the field insulating structure 110 may include a portion located between a pair of source/drain regions 130 in the second horizontal direction (the Y direction) to be adjacent to each of the pair of source/drain regions 130. The second buried insulating film 116 of the field insulating structure 110 may have an upper surface 116T2 contacting the insulating liner 142 of the inter-gate insulating structure 140 between the pair of source/drain regions 130. Herein, the upper surface 116T2, which contacts the inter-gate insulating structure 140, of the second buried insulating film 116, in the upper surface of the second buried insulating film 116, may be referred to as a second upper surface. As shown in FIG. 4, the upper surface 116T2, which contacts the inter-gate insulating structure 140, of the second buried insulating film 116, in the upper surface of the second buried insulating film 116, may have a concave shape toward or relative to the inter-gate insulating structure 140.

A plurality of second insulating spacers 119 may be arranged on the field insulating structure 110 located between the pair of source/drain regions 130. Each of the plurality of second insulating spacers 119 may cover or overlap a sidewall of a portion of the source/drain region 130 in the second horizontal direction (Y direction), the portion being adjacent to the fin-type active region F1. Each of the plurality of second insulating spacers 119 may be in contact with the sidewall of the source/drain region 130. The plurality of second insulating spacers 119 may be covered or overlapped by the inter-gate insulating structure 140 in the second horizontal direction (Y direction). The plurality of source/drain regions 130 and the plurality of second insulating spacers 119 may each have a surface contacting the insulating liner 142 of the inter-gate insulating structure 140. The plurality of second insulating spacers 119 and the inter-gate insulating structure 140 may each be in contact with the upper surface of the second buried insulating film 116 of the field insulating structure 110.

Each of the plurality of second insulating spacers 119 may include the same material as the constituent material of the first insulating spacer 118. In some embodiments, at least some of the plurality of second insulating spacers 119 may be omitted.

As shown in FIGS. 2 and 4, a plurality of source/drain contacts CA may be respectively arranged on the plurality of source/drain regions 130. Each of the plurality of source/drain contacts CA may pass or extend through the inter-gate insulating structure 140 including the inter-gate dielectric 144 and the insulating liner 142 in the vertical direction (the Z direction) and may be configured to be electrically connected to at least one source/drain region 130 selected from the plurality of source/drain regions 130. Each of the plurality of source/drain contacts CA may be in contact with the metal silicide film 172 formed on the source/drain region 130. Each of the plurality of source/drain contacts CA may be configured to be electrically connected to the source/drain region 130 via the metal silicide film 172. Each of the plurality of source/drain contacts CA may be spaced apart from the main gate portion 160M of the gate line 160 in the first horizontal direction (the X direction) with the first insulating spacer 118 therebetween.

Each of the plurality of source/drain contacts CA may include a conductive barrier film 174 and a metal plug 176. The lower surface and the sidewall of the metal plug 176 may be covered or overlapped by the conductive barrier film 174. The conductive barrier film 174 may include a metal or a conductive metal nitride. For example, the conductive barrier film 174 may include, but is not limited to, Ti, Ta, W, TiN, TaN, WN, WCN, TiSiN, TaSiN, WSiN, or a combination thereof. The metal plug 176 may include, but is not limited to, molybdenum (Mo), tungsten (W), cobalt (Co), ruthenium (Ru), manganese (Mn), titanium (Ti), tantalum (Ta), aluminum (Al), copper (Cu), a combination thereof, or an alloy thereof. In some embodiments, the conductive barrier film 174 may be omitted from each of the plurality of source/drain contacts CA.

The upper surface of each of the source/drain contact CA, the capping insulating pattern 164, and the inter-gate insulating structure 140 may be covered by an upper insulating structure 185. The upper insulating structure 185 may include an etch stop film 186 and an upper insulating film 187, which are stacked in the stated order on each of the plurality of source/drain contacts CA, the plurality of insulating patterns 164, and the inter-gate insulating structure 140. The etch stop film 186 may include silicon carbide (SiC), SiN, SiCN, SiOC, AlN, AlON, AlO, AlOC, or a combination thereof. The upper insulating film 187 may include an oxide film, a nitride film, an ultra-low k (ULK) film having an ultra-low dielectric constant of about 2.2 to about 2.4, or a combination thereof. For example, the upper insulating film 187 may include, but is not limited to, tetraethylorthosilicate (TEOS) film, a high-density plasma (HDP) oxide film, a a borophosphosilicate glass (BPSG) film, a flowable chemical vapor deposition (FCVD) oxide film, a SiON film, a SiN film, a SiOC film, a SiCOH film, or a combination thereof.

As shown in FIGS. 2 and 4, a source/drain via contact VA may be arranged on the source/drain contact CA. A plurality of source/drain via contacts VA may each be in contact with the source/drain contact CA and extend through the upper insulating structure 185. The source/drain region 130 connected to the source/drain contact CA, among the plurality of source/drain regions 130, may be configured to be electrically connected to the source/drain via contact VA via the metal silicide film 172 and the source/drain contact CA. Each of the plurality of source/drain via contacts VA may include, but is not limited to, molybdenum (Mo) or tungsten (W).

As shown in FIG. 2, a gate contact CB may be arranged on the gate line 160. The gate contact CB may be configured to pass or extend through the upper insulating structure 185 and the capping insulating pattern 164 in the vertical direction (the Z direction) and to be connected to the gate line 160. The lower surface of the gate contact CB may be in contact with the upper surface of the gate line 160. The gate contact CB may include a contact plug including molybdenum (Mo), copper (Cu), tungsten (W), cobalt (Co), ruthenium (Ru), manganese (Mn), titanium (Ti), tantalum (Ta), aluminum (Al), a combination thereof, or an alloy thereof. In some embodiments, the gate contact CB may further include a conductive barrier pattern at least partially surrounding a portion of the contact plug. The conductive barrier pattern of the gate contact CB may include a metal or a metal nitride. For example, the conductive barrier pattern may include Ti, Ta, W, TiN, TaN, WN, WCN, TiSiN, TaSiN, WSiN, or a combination thereof.

The integrated circuit device 100 described with reference to FIGS. 1 to 5 includes the field insulating structure 110 between a pair of fin-type active regions F1 that are adjacent to each other in the second horizontal direction (the Y direction), among the plurality of fin-type active regions F1, and the field insulating structure 110 includes the insulating liner 114 and the second buried insulating film 116, which sequentially cover or overlap the upper surface of the first buried insulating film 112 in the vertical direction (Z direction) and in the stated order, in an upper portion thereof adjacent to the gate line 160 out of the substrate 102 and the gate line 160. The second buried insulating film 116 is formed in advance before processes to form the gate line 160 are performed, and may prevent or inhibit the upper surface of the field insulating structure 110 from being unintentionally lowered due to various etching processes performed while the processes required to form the gate line 160 are being performed. Therefore, during the process of fabricating the integrated circuit device 100, a portion sagging toward the substrate 102 may be prevented from being formed in the gate line 160 between the pair of fin-type active regions F1 and thus having a lower surface that has a convex shape toward or relative to the substrate 102. Therefore, due to the second buried insulating film 116 of the field insulating structure 110, a sufficient insulating space between the gate line 160 and the pair of fin-type active regions F1 may be secured, and parasitic capacitance generated due to the coupling between the gate line 160 and the pair of fin-type active regions F1 may be reduced. Therefore, there may be a contribution to improving the performance and reliability of each of the plurality of transistors in the integrated circuit device 100.

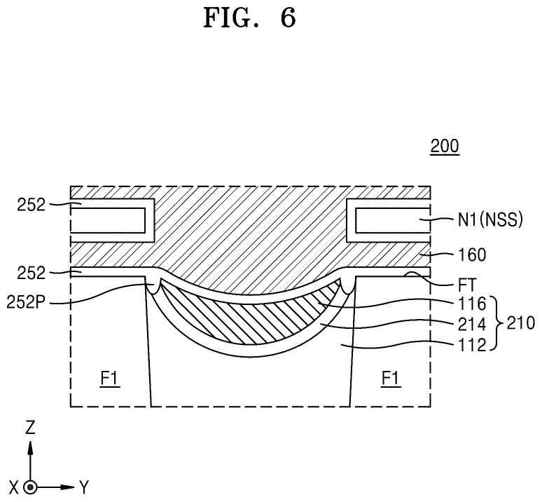

FIG. 6 is a cross-sectional view illustrating an integrated circuit device 200 according to some embodiments. FIG. 6 illustrates an enlarged cross-sectional configuration of a portion of the integrated circuit device 200, which corresponds to the region EX1 of FIG. 3. In FIG. 6, the same reference numerals as in FIGS. 1 to 5 respectively denote the same members, and repeated descriptions thereof are omitted hereinafter.

Referring to FIG. 6, the integrated circuit device 200 may have substantially the same configuration as the integrated circuit device 100 described with reference to FIGS. 1 to 5. However, the integrated circuit device 200 includes a field insulating structure 210 and a gate dielectric film 252.

The field insulating structure 210 has substantially the same configuration as the field insulating structure 110 described with reference to FIGS. 3 to 5. However, the field insulating structure 210 may include a first buried insulating film 112 contacting the sidewall of each of a pair of fin-type active regions F1 adjacent to the field insulating structure 210 in the second horizontal direction (the Y direction), an insulating liner 214 arranged between the pair of fin-type active regions F1 and covering or overlapping the upper surface of the first buried insulating film 112 in the vertical direction (Z direction), and a second buried insulating film 116 arranged between the pair of fin-type active regions F1 and covering or overlapping the upper surface of the insulating liner 214 in the vertical direction (Z direction). The first buried insulating film 112 and the second buried insulating film 116 may respectively have the same configurations as described with reference to FIGS. 3 to 5. The insulating liner 214 may have substantially the same configuration as the insulating liner 114 described with reference to FIGS. 3 to 5. However, a separation distance in the vertical direction (the Z direction) between the uppermost surface of the insulating liner 214, which is adjacent to the gate line 160, and the gate line 160 may be greater than a separation distance in the vertical direction (the Z direction) between the upper surface of the second buried insulating film 116, which contacts the gate dielectric film 252, and the gate line 160.

The gate dielectric film 252 has substantially the same configuration as the gate dielectric film 152 described with reference to FIGS. 2 to 5. However, the gate dielectric film 252 may include a plurality of protrusions 252P protruding or extending in a direction away from the gate line 160, that is, a direction toward the substrate 102 (see FIGS. 2 and 3). Each of the plurality of protrusions 252P of the gate dielectric film 252 may be in contact with one fin-type active region F1 selected from a pair of fin-type active regions F1 that are adjacent to the field insulating structure 210 in the second horizontal direction (the Y direction). Each of the plurality of protrusions 252P of the gate dielectric film 252 may be arranged between the fin-type active region F1 and the second buried insulating film 116.

The lowermost surface, which is closest to the substrate 102 (see FIGS. 2 to 4), of the second buried insulating film 116 of the field insulating structure 210 may be closer to the substrate 102 than the lowermost surface, which is closest to the substrate 102 (see FIGS. 2 to 4), of the protrusion 252P of the gate dielectric film 252. In the field insulating structure 210, each of the insulating liner 214 and the second buried insulating film 116 may be apart from the fin-type active region F1 in the second horizontal direction (the Y direction).

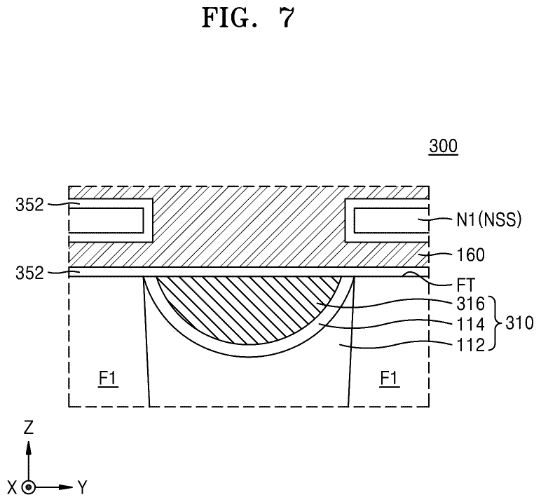

FIG. 7 is a cross-sectional view illustrating an integrated circuit device 300 according to some embodiments. FIG. 7 illustrates an enlarged cross-sectional configuration of a portion of the integrated circuit device 300, which corresponds to the region EX1 of FIG. 3. In FIG. 7, the same reference numerals as in FIGS. 1 to 5 respectively denote the same members, and repeated descriptions thereof are omitted hereinafter.

Referring to FIG. 7, the integrated circuit device 300 may have substantially the same configuration as the integrated circuit device 100 described with reference to FIGS. 1 to 5. However, the integrated circuit device 300 includes a field insulating structure 310 and a gate dielectric film 352.

The field insulating structure 310 has substantially the same configuration as the field insulating structure 110 described with reference to FIGS. 3 to 5. However, the field insulating structure 310 may include a first buried insulating film 112 contacting the sidewall of each of a pair of fin-type active regions F1 adjacent to the field insulating structure 310 in the second horizontal direction (the Y direction), an insulating liner 114 arranged between the pair of fin-type active regions F1 and covering or overlapping the upper surface of the first buried insulating film 112 in the vertical direction (Z direction), and a second buried insulating film 316 arranged between the pair of fin-type active regions F1 and covering or overlapping the upper surface of the insulating liner 114 in the vertical direction (Z direction). The first buried insulating film 112 and the insulating liner 114 may respectively have the same configurations as described with reference to FIGS. 3 to 5. The second buried insulating film 316 may have substantially the same configuration as the second buried insulating film 116 described with reference to FIGS. 3 to 5. However, the upper surface of the second buried insulating film 316, which contacts the gate dielectric film 352, may extend flat or linearly in the second horizontal direction (the Y direction). The uppermost surface of the insulating liner 114 and the uppermost surface of the second buried insulating film 316 may each be in contact with the gate dielectric film 352 and may extend along one plane at the same vertical level over or on the substrate 102 (see FIGS. 2 to 4).

The gate dielectric film 352 has substantially the same configuration as the gate dielectric film 152 described with reference to FIGS. 2 to 5. However, in the gate dielectric film 352, a portion contacting the fin top surface FT of the fin-type active region F1 and a portion contacting the upper surface of the second buried insulating film 316 may extend along one plane at the same vertical level over or on the substrate 102 (see FIGS. 2 to 4).

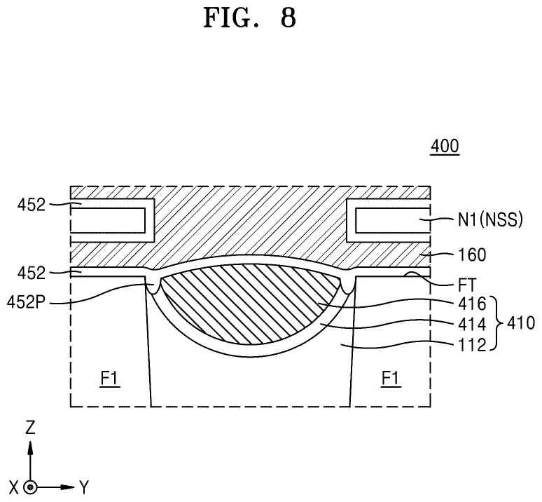

FIG. 8 is a cross-sectional view illustrating an integrated circuit device 400 according to some embodiments. FIG. 8 illustrates an enlarged cross-sectional configuration of a portion of the integrated circuit device 400, which corresponds to the region EX1 of FIG. 3. In FIG. 8, the same reference numerals as in FIGS. 1 to 5 respectively denote the same members, and repeated descriptions thereof are omitted hereinafter.

Referring to FIG. 8, the integrated circuit device 400 may have substantially the same configuration as the integrated circuit device 100 described with reference to FIGS. 1 to 5. However, the integrated circuit device 400 includes a field insulating structure 410 and a gate dielectric film 452.

The field insulating structure 410 has substantially the same configuration as the field insulating structure 110 described with reference to FIGS. 3 to 5. However, the field insulating structure 410 may include a first buried insulating film 112 contacting the sidewall of each of a pair of fin-type active regions F1 adjacent to the field insulating structure 410 in the second horizontal direction (the Y direction), an insulating liner 414 arranged between the pair of fin-type active regions F1 and covering or overlapping the upper surface of the first buried insulating film 112 in the vertical direction (Z direction), and a second buried insulating film 416 arranged between the pair of fin-type active regions F1 and covering or overlapping the upper surface of the insulating liner 414 in the vertical direction (Z direction). The first buried insulating film 112 may have the same configuration as described with reference to FIGS. 3 to 5. The insulating liner 414 may have substantially the same configuration as the insulating liner 114 described with reference to FIGS. 3 to 5. However, a separation distance in the vertical direction (the Z direction) between the uppermost surface of the insulating liner 414, which is adjacent to the gate line 160, and the gate line 160 may be greater than a separation distance in the vertical direction (the Z direction) between the upper surface of the second buried insulating film 416, which contacts the gate dielectric film 452, and the gate line 160.

The second buried insulating film 416 may have substantially the same configuration as the second buried insulating film 116 described with reference to FIGS. 3 to 5. The upper surface, which contacts the gate dielectric film 452, of the second buried insulating film 416 of the field insulating structure 410 may have a convex shape toward or relative to the gate line 160.

The gate dielectric film 452 may have substantially the same configuration as the gate dielectric film 152 described with reference to FIGS. 2 to 5. However, the gate dielectric film 452 may include a plurality of protrusions 452P protruding or extending in a direction away from the gate line 160, that is, a direction toward the substrate 102 (see FIGS. 2 and 3). Each of the plurality of protrusions 452P of the gate dielectric film 452 may be in contact with one fin-type active region F1 selected from a pair of fin-type active regions F1 that are adjacent to the field insulating structure 410 in the second horizontal direction (the Y direction). Each of the plurality of protrusions 452P of the gate dielectric film 452 may be arranged between the fin-type active region F1 and the second buried insulating film 416.

The lowermost surface, which is closest to the substrate 102 (see FIGS. 2 to 4), of the second buried insulating film 416 of the field insulating structure 410 may be closer to the substrate 102 than the lowermost surface, which is closest to the substrate 102 (see FIGS. 2 to 4), of the protrusion 452P of the gate dielectric film 452. In the field insulating structure 410, each of the insulating liner 414 and the second buried insulating film 416 may be spaced apart from the fin-type active region F1 in the second horizontal direction (the Y direction).

Similar to the integrated circuit device 100 described with reference to FIGS. 1 to 5, the integrated circuit devices 200, 300, and 400 respectively include the field insulating structures 210, 310, and 410 each arranged between a pair of fin-type active regions F1 adjacent to each other in the second horizontal direction (the Y direction), among the plurality of fin-type active regions F1. The field insulating structures 210, 310, and 410 respectively include the second buried insulating films 116, 316, and 416, thereby preventing the upper surface of each of the field insulating structures 210, 310, and 410 from being unintentionally lowered due to various etching processes performed while the processes required to form the gate line 160 in the fabrication process of each of the integrated circuit devices 200, 300, and 400 are being performed. Therefore, the gate line 160 may be prevented from having a sagging portion formed between the pair of fin-type active regions F1 and thus having a lower surface that is convex toward or relative to the substrate 102, and a sufficient insulating space between the gate line 160 and the pair of fin-type active regions F1 may be secured. Therefore, parasitic capacitance generated due to the coupling between the gate line 160 and the pair of fin-type active regions F1 may be reduced, and there may be a contribution to improving the performance and reliability of each of the plurality of transistors.

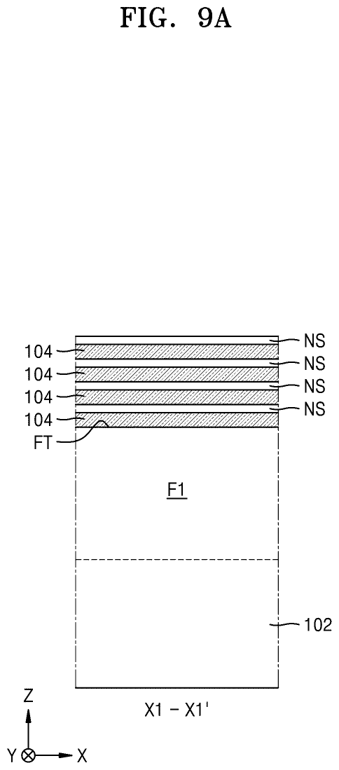

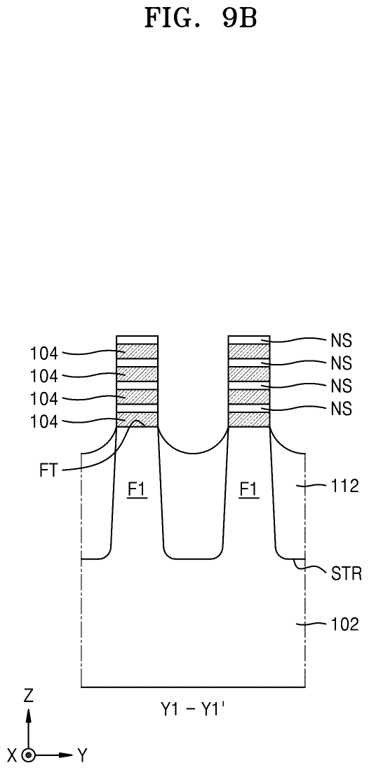

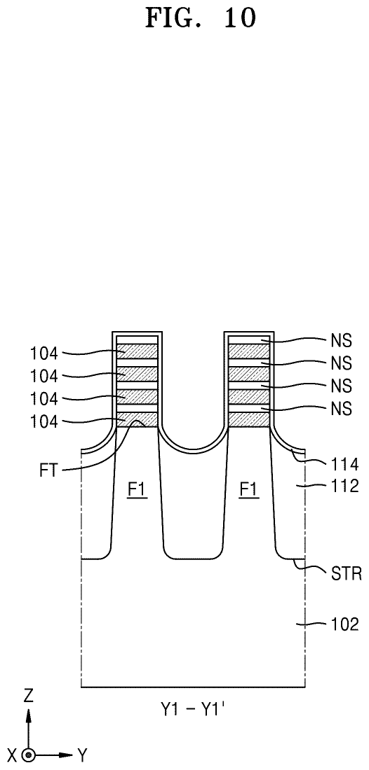

FIGS. 9A to 21B are cross-sectional views illustrating a sequence of processes of a method of fabricating an integrated circuit device, according to some embodiments. More specifically, FIGS. 9A, 15A, 16, 17, 18, 19A, 20A, and 21A are cross-sectional views illustrating some components in a region corresponding to the cross-section taken along the line X1-X1′ of FIG. 1, according to the sequence of processes, and FIGS. 9B, 10, 11, 12, 13, 15B, 19B, 20B, and 21B are cross-sectional views illustrating some components in a region corresponding to the cross-section taken along the line Y1-Y1′ of FIG. 1, according to the sequence of processes. An example of a method of fabricating the integrated circuit device 100 described with reference to FIGS. 1 to 5 is described with reference to FIGS. 9A to 21B. In FIGS. 9A to 21B, the same reference numerals as in FIGS. 1 to 5 respectively denote the same members, and here, repeated descriptions thereof are omitted.

Referring to FIGS. 9A and 9B, a multilayer, in which a plurality of sacrificial semiconductor layers 104 and a plurality of nanosheet semiconductor layers NS are alternately stacked one-by-one, may be formed on the substrate 102, followed by etching a portion of each of the multilayer and the substrate 102, thereby forming a device isolation trench STR in the substrate 102. As a result, a plurality of fin-type active regions F1 may be formed to protrude or extend upwards in the vertical direction (the Z direction) from the substrate 102, and the plurality of sacrificial semiconductor layers 104 and the plurality of nanosheet semiconductor layers NS may remain on the fin top surface FT of each of the plurality of fin-type active regions F1 and extend lengthwise in the first horizontal direction (the X direction).

Each of the plurality of sacrificial semiconductor layers 104 and each of the plurality of nanosheet semiconductor layers NS may respectively include semiconductor materials having different etch selectivities. In some embodiments, each of the plurality of nanosheet semiconductor layers NS may include a Si layer, and each of the plurality of sacrificial semiconductor layers 104 may include a SiGe layer. In some embodiments, the amount of Ge may be constant in the plurality of sacrificial semiconductor layers 104. The SiGe layer constituting each of the plurality of sacrificial semiconductor layers 104 may include Ge in a constant amount selected from a range of about 5 at % to about 60 at %, for example, about 10 at % to about 40 at %. The amount of Ge in the SiGe layer constituting each of the plurality of sacrificial semiconductor layers 104 may be variously selected as needed.

Next, a first buried insulating film 112 may be formed on the substrate 102 to partially or completely fill the device isolation trench STR. After the first buried insulating film 112 is formed, a level of the upper surface of the first buried insulating film 112 may be lower than a level of the fin top surface FT of each of the plurality of fin-type active regions F1. In some embodiments, to form the first buried insulating film 112, a CVD process may be used. The first buried insulating film 112 may include a silicon oxide film.

Referring to FIG. 10, an insulating liner 114 may be formed to conformally cover or overlap exposed surfaces in the resulting product of FIGS. 9A and 9B in the vertical direction (Z direction). To form the insulating liner 114, an ALD process may be used. In some embodiments, the insulating liner 114 may include a silicon oxide film. By forming the insulating liner 114 by the ALD process, the density of the silicon oxide film constituting the insulating liner 114 may be greater than the density of the silicon oxide film constituting the first buried insulating film 112.

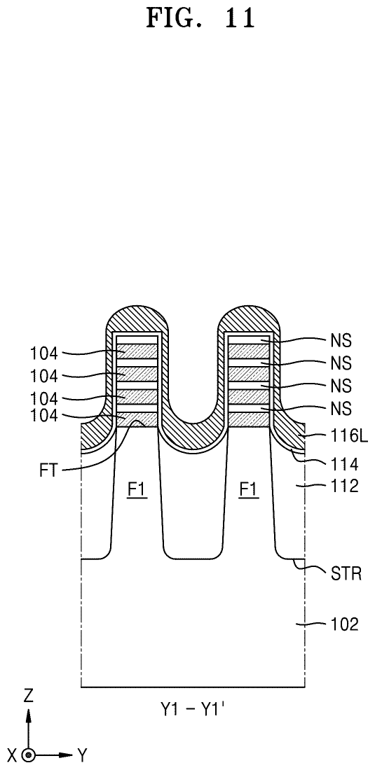

Referring to FIG. 11, a preliminary buried insulating film 116L may be formed on the resulting product of FIG. 10. To form the preliminary buried insulating film 116L, a CVD process may be used. Here, by controlling CVD process conditions, the preliminary buried insulating film 116L may be formed with a relatively large thickness on the upper surface of each of the first buried insulating film 112 and the stack structure of the plurality of sacrificial semiconductor layers 104 and the plurality of nanosheet semiconductor layers NS, and the preliminary buried insulating film 116L may be formed with a relatively small thickness on the sidewall of the stack structure of the plurality of sacrificial semiconductor layers 104 and the plurality of nanosheet semiconductor layers NS. The preliminary buried insulating film 116L may include a silicon nitride (SiN) film.

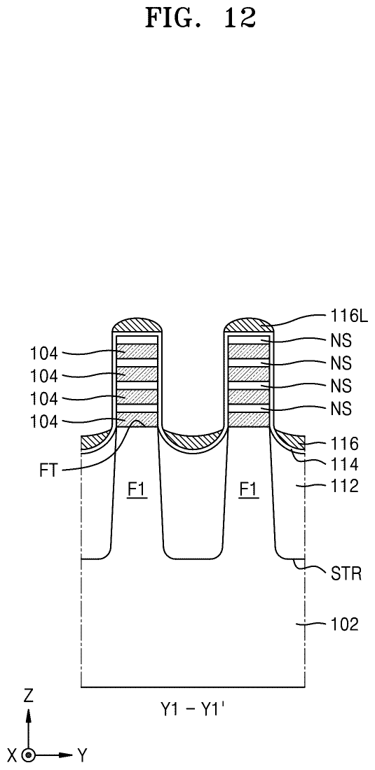

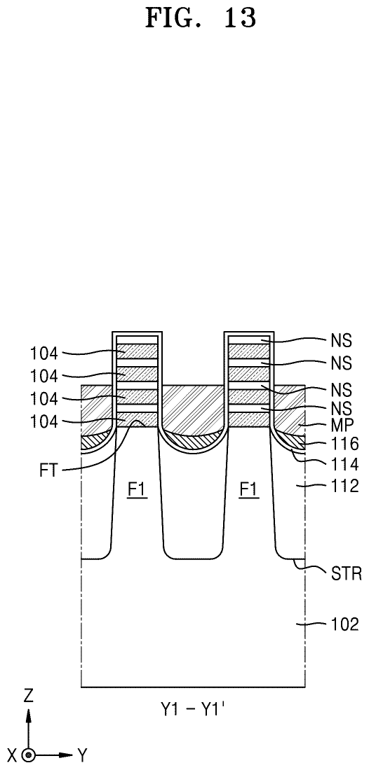

Referring to FIG. 12, the resulting product of FIG. 11 may be cleaned, thereby removing portions of the preliminary buried insulating film 116L, which have relatively small thicknesses. As a result, the sidewall of the stack structure of the plurality of sacrificial semiconductor layers 104 and the plurality of nanosheet semiconductor layers NS may be exposed, and a second buried insulating film 116 including a remaining portion of the preliminary buried insulating film 116L may remain on the upper surface of the first buried insulating film 112. A portion of the preliminary buried insulating film 116L may also remain on the upper surface of the stack structure of the plurality of sacrificial semiconductor layers 104 and the plurality of nanosheet semiconductor layers NS. In some embodiments, a diluted hydrofluoric acid (DHF) solution may be used for the cleaning process, but the present disclosure is not limited thereto.

Referring to FIG. 13, in the resulting product of FIG. 12, a mask pattern MP may be formed to cover or overlap the second buried insulating film 116 in the vertical direction (Z direction). The mask pattern MP may include a material having etch selectivity with respect to each of the insulating liner 114, the second buried insulating film 116, the plurality of sacrificial semiconductor layers 104, and the plurality of nanosheet semiconductor layers NS. In some embodiments, the mask pattern MP may include, but is not limited to, a carbon-containing material, such as a spin-on-hardmask (SOH).

After the mask pattern MP is formed, the remaining portion of the preliminary buried insulating film 116L, which is on the upper surface of the stack structure of the plurality of sacrificial semiconductor layers 104 and the plurality of nanosheet semiconductor layers NS, may be removed by using the mask pattern MP as an etch mask. To remove the remaining portion of the preliminary buried insulating film 116L, a phosphoric acid solution may be used. After the remaining portion of the preliminary buried insulating film 116L is removed, the insulating liner 114 may be exposed around the mask pattern MP.

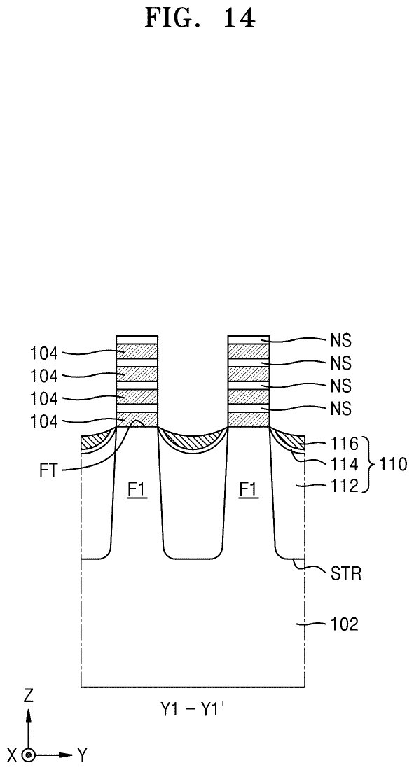

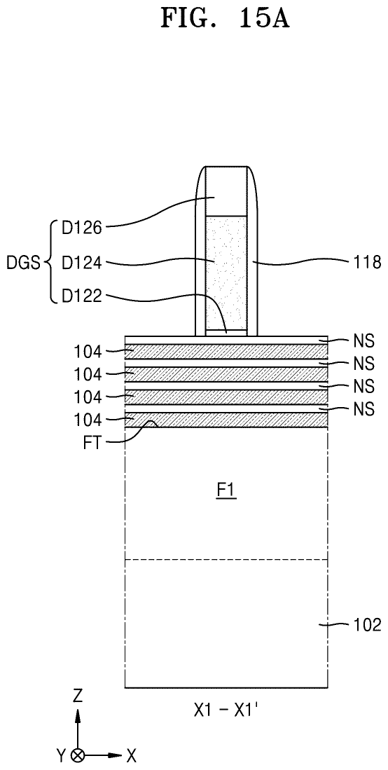

Referring to FIG. 14, the insulating liner 114 exposed by the mask pattern MP may be removed from the resulting product of FIG. 13, thereby exposing the upper surface and the sidewall of the stack structure of the plurality of sacrificial semiconductor layers 104 and the plurality of nanosheet semiconductor layers NS. Next, the mask pattern MP may be removed. To remove the mask pattern MP, ashing and strip processes may be used. While the mask pattern MP is being removed, the insulating liner 114 between the mask pattern MP and the stack structure of the plurality of sacrificial semiconductor layers 104 and the plurality of nanosheet semiconductor layers NS may be removed together with the mask pattern MP, thereby exposing the sidewall of each of the plurality of sacrificial semiconductor layers 104 and the plurality of nanosheet semiconductor layers NS.

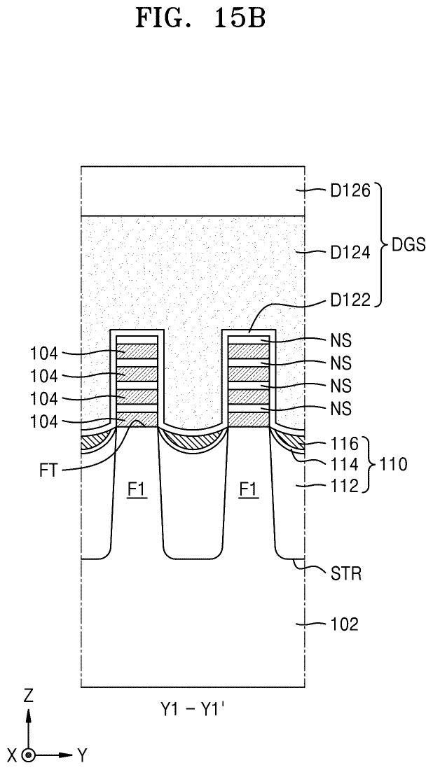

Referring to FIGS. 15A and 15B, a dummy gate structure DGS may be formed on the resulting product having undergone the process described with reference to FIG. 14, and a plurality of first insulating spacers 118 may be formed to respectively cover or overlap both sidewalls of the dummy gate structure DGS in the first horizontal direction (X direction). During the formation of the plurality of first insulating spacers 118, a plurality of second insulating spacers 119 shown in FIG. 4 may also be formed.

The dummy gate structure DGS may be formed over or on the substrate 102 to extend lengthwise in the second horizontal direction (the Y direction) intersecting with the fin-type active region F1. Each dummy gate structure DGS may have a structure in which an oxide film D122, a dummy gate layer D124, and a capping layer D126 are stacked in the stated order. In some embodiments, the dummy gate layer D124 may include polysilicon, and the capping layer D126 may include a silicon nitride film.

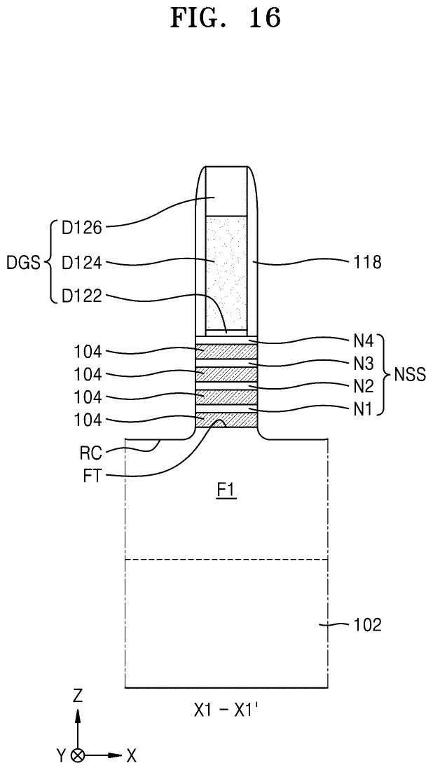

Referring to FIG. 16, a portion of each of the plurality of sacrificial semiconductor layers 104 and the plurality of nanosheet semiconductor layers NS and a portion of the fin-type active region F1 may be etched by using the dummy gate structure DGS and the plurality of first insulating spacers 118 as an etch mask, thereby dividing the plurality of nanosheet semiconductor layers NS into a plurality of nanosheet stacks NSS and forming a plurality of recesses RC in an upper portion of the fin-type active region F1. Each of the plurality of nanosheet stacks NSS may include a first nanosheet N1, a second nanosheet N2, a third nanosheet N3, and a fourth nanosheet N4. To form the plurality of recesses RC, etching may be performed by dry etching, wet etching, or a combination thereof. After the plurality of recesses RC are formed, the resulting product, in which the plurality of second insulating spacers 119 protrude or extend above the lower surface of a recess RC, may be obtained as shown in FIG. 4.

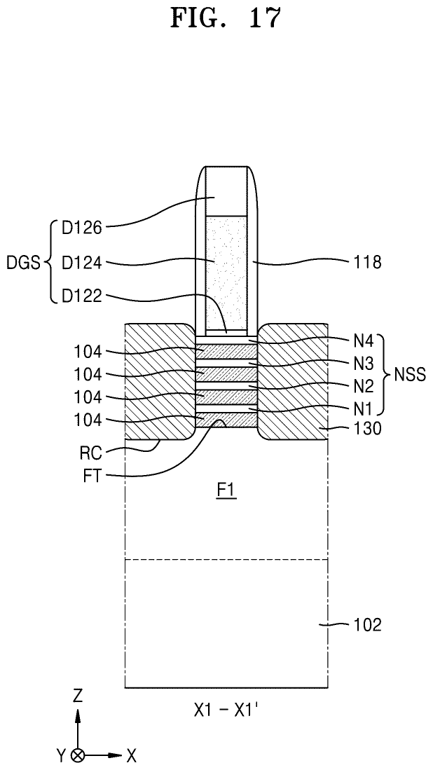

Referring to FIG. 17, in the resulting product of FIG. 16, a plurality of source/drain regions 130 may be formed to respectively and at least partially fill the plurality of recesses RC. To form the plurality of source/drain regions 130, a semiconductor material may be epitaxially grown on a surface of the fin-type active region F1, which is exposed at the lower surface of each of the plurality of recesses RC, and on the sidewall of each of the first nanosheet N1, the second nanosheet N2, the third nanosheet N3, and the fourth nanosheet N4 of the nanosheet stack NSS.

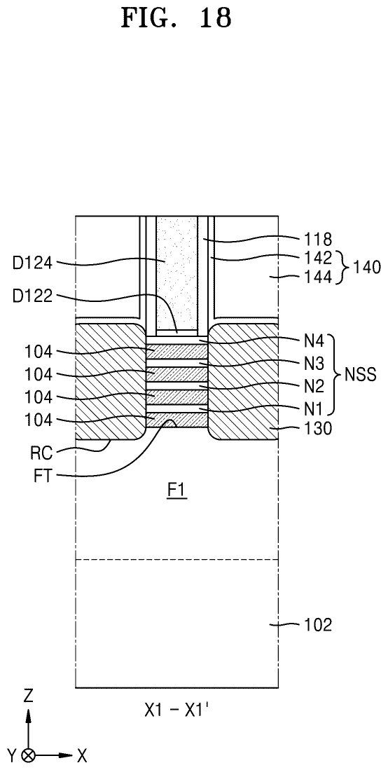

Referring to FIG. 18, an insulating liner 142 may be formed to cover or overlap the resulting product of FIG. 17 in the first horizonal direction (X direction), and an inter-gate dielectric 144 may be formed on the insulating liner 142, thereby forming an inter-gate insulating structure 140. Next, a portion of the inter-gate insulating structure 140 may be etched, thereby exposing the respective upper surfaces of the plurality of capping layers D126. Next, the dummy gate layer D124 may be exposed by removing the plurality of capping layers D126, and a portion of the inter-gate insulating structure 140 may be removed such that the upper surface of the inter-gate insulating structure 140 and the upper surface of the dummy gate layer D124 are at an approximately equal level.

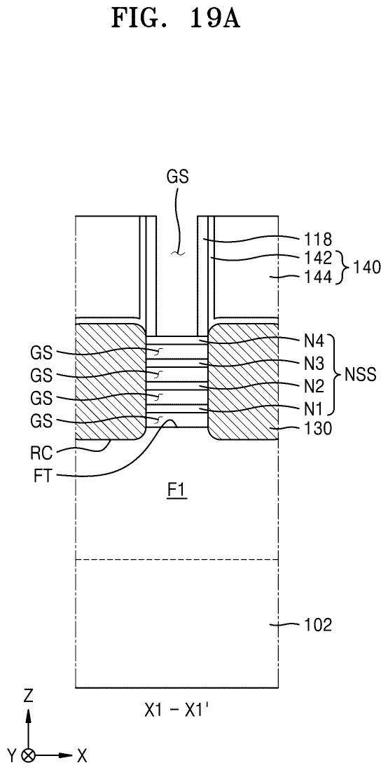

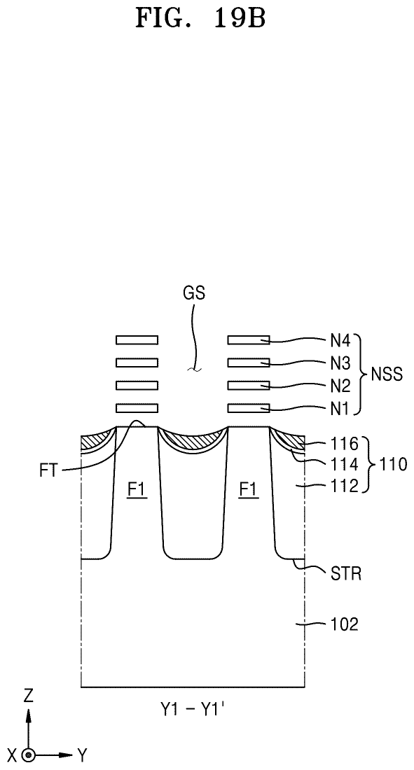

Referring to FIGS. 19A and 19B, a gate space GS may be prepared by removing the dummy gate layer D124 and the oxide film D122 thereunder from the resulting product of FIG. 18, and the plurality of nanosheet stacks NSS may each be exposed by the gate space GS. Next, by removing the plurality of sacrificial semiconductor layers 104 remaining on or over the fin-type active region F1 through the gate space GS, the gate space GS may expand up to each space between the first nanosheet N1, the second nanosheet N2, the third nanosheet N3, and the fourth nanosheet N4 and a space between the first nanosheet N1 and the fin top surface FT of the fin-type active region F1. In some embodiments, to selectively remove the plurality of sacrificial semiconductor layers 104, the difference in etch selectivity between each of the first nanosheet N1, the second nanosheet N2, the third nanosheet N3, and the fourth nanosheet N4 and each of the plurality of sacrificial semiconductor layers 104 may be used.

To selectively remove the plurality of sacrificial semiconductor layers 104, a liquid-phase or gas-phase etchant may be used. In some embodiments, to selectively remove the plurality of sacrificial semiconductor layers 104, a CH₃COOH-based etching solution, for example, an etching solution including a mixture of CH₃COOH, HNO₃, and HF, or an etching solution including a mixture of CH₃COOH, H₂O₂, and HF, may be used, but the present disclosure is not limited thereto.

After the process of removing the dummy gate layer D124 and the oxide film D122 thereunder is performed as described above, the second buried insulating film 116 may be exposed around each of the plurality of fin-type active regions F1. Because the second buried insulating film 116 includes a nitride film, the second buried insulating film 116 exposed at the upper surface of the field insulating structure 110 may protect the first buried insulating film 112 and the insulating liner 114 while the process of removing the dummy gate layer D124 and the oxide film D122 thereunder is being performed, and as a result, an issue, such as the consumption of the field insulating structure 110 due to an etching atmosphere, a reduction in the height of the upper surface of the field insulating structure 110, or the like, may be prevented or inhibited. In addition, even while an etching process for selectively removing the plurality of sacrificial semiconductor layers 104 is being performed as described above, an issue, such as the consumption of the field insulating structure 110 due to an etching atmosphere, a reduction in the height of the upper surface of the field insulating structure 110, or the like, may be prevented or inhibited similar to the case where the process of removing the dummy gate layer D124 and the oxide film D122 thereunder is performed.

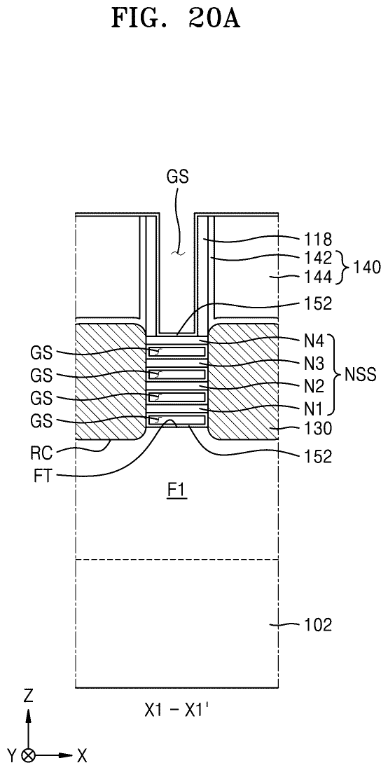

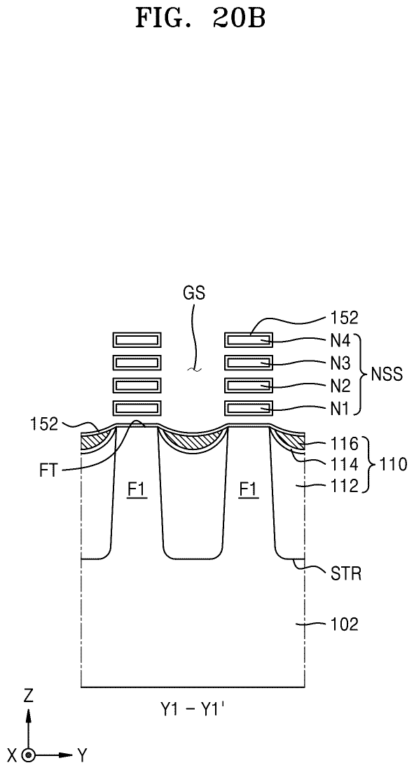

Referring to FIGS. 20A and 20B, in the resulting product of FIGS. 19A and 19B, a gate dielectric film 152 may be formed to cover or overlap respective exposed surfaces of the first nanosheet N1, the second nanosheet N2, the third nanosheet N3, the fourth nanosheet N4, and the fin-type active region F1 in the vertical direction (Z direction). To form the gate dielectric film 152, an ALD process may be used.

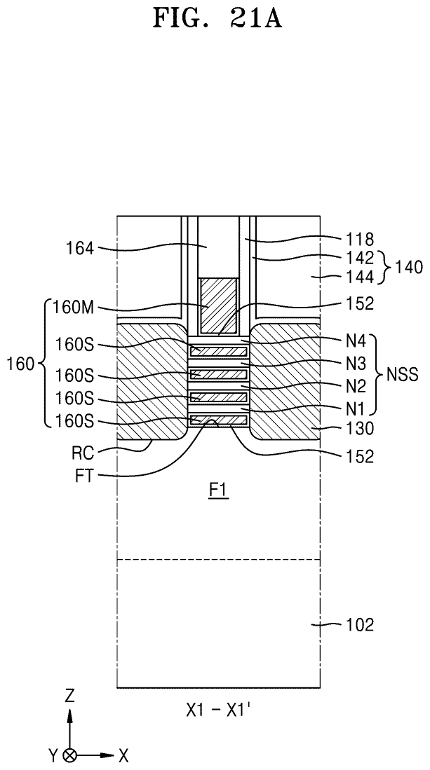

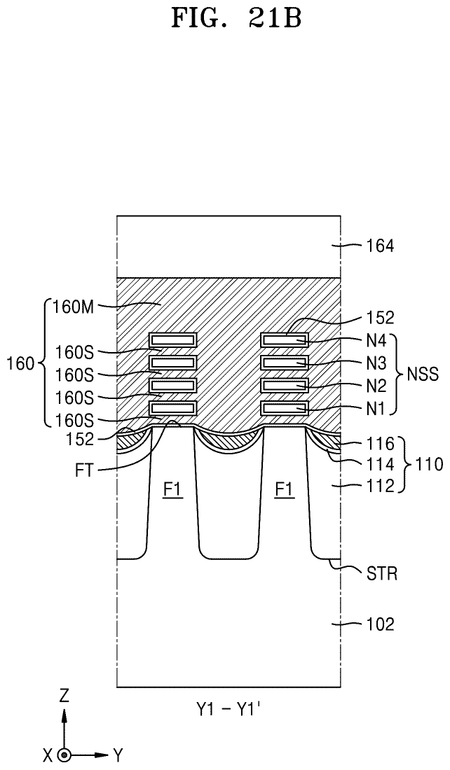

Referring to FIGS. 21A and 21B, a gate line 160 may be formed on the gate dielectric film 152 to at least partially fill the gate space GS (see FIGS. 20A and 20B). Next, the respective heights of the gate line 160 and the gate dielectric film 152 may be reduced by removing respective portions of the gate line 160 and the gate dielectric film 152 from the respective upper surfaces thereof, and a of capping insulating patterns 164 may each be formed to cover or overlap the upper surface of each of the gate line 160 and the gate dielectric film 152 in the vertical direction (Z direction).

Next, as shown in FIGS. 2 to 4, a plurality of source/drain contact holes may be formed to respectively expose the plurality of source/drain regions 130 through etching of portions of the inter-gate insulating structure 140, followed by forming a metal silicide film 172 on a surface of the source/drain region 130, which is exposed by each of the plurality of source/drain contact holes, and then, a conductive barrier film 174 and a metal plug 176 may be formed in the stated order on the metal silicide film 172, thereby forming a plurality of source/drain contacts CA to respectively and at least partially fill the plurality of source/drain contact holes.

Next, an etch stop film 186 and an upper insulating film 187 may be formed in the stated order to cover or overlap the upper surface of each of the plurality of source/drain contacts CA, the capping insulating pattern 164, and the inter-gate insulating structure 140 in the vertical direction (Z direction), thereby forming an upper insulating structure 185. Next, a source/drain via contact VA, which passes or extends through the upper insulating structure 185 in the vertical direction (the Z direction) and is connected to the source/drain contact CA, and a gate contact CB, which passes or extends through the upper insulating structure 185 and the capping insulating pattern 164 in the vertical direction (the Z direction) and is connected to the gate line 160, may be formed. The source/drain via contact VA and the gate contact CB may be simultaneously formed or may be formed by separate processes from each other.

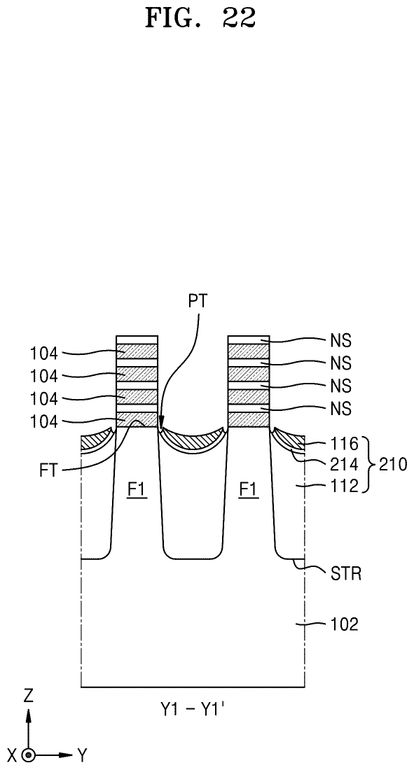

FIG. 22 is a cross-sectional view illustrating a method of fabricating an integrated circuit device, according to some embodiments, and illustrates some components in a region corresponding to the cross-section taken along the line Y1-Y1′ of FIG. 1, according to a process sequence. An example of a method of fabricating the integrated circuit device 200 described with reference to FIG. 6 is described with reference to FIG. 22. In FIG. 22, the same reference numerals as in FIGS. 1 to 21B respectively denote the same members, and here, repeated descriptions thereof are omitted.

Referring to FIG. 22, the processes described with reference to FIGS. 9A to 14 may be performed. However, in the process described with reference to FIG. 14, when the insulating liner 114 between the mask pattern MP and the stack structure of the plurality of sacrificial semiconductor layers 104 and the plurality of nanosheet semiconductor layers NS is removed, the removal amount of the insulating liner 114 may be increased, thereby forming a gap PT between the fin-type active region F1 and the second buried insulating film 116 to extend toward the substrate 102 and forming an insulating liner 214 that includes the remaining portion of the insulating liner 114.

Next, the processes described with reference to FIGS. 15A to 20B may be performed on the resulting product having undergone the process described with reference to FIG. 22. However, in the process described with reference to FIGS. 20A and 20B, a gate dielectric film 252 having a plurality of protrusions 252P, as shown in FIG. 6, may be formed instead of the gate dielectric film 152. Next, the processes described with reference to FIGS. 21A and 21B may be performed, thereby fabricating the integrated circuit device 200 described with reference to FIG. 6.

Heretofore, while the examples of the methods of fabricating the integrated circuit devices 100 and 200 shown in FIGS. 1 to 6 have been described with reference to FIGS. 9A to 22, it will be understood by those of ordinary skill in the art that, by making various modifications and changes to the examples described with reference to FIGS. 9A to 22 without departing from the spirit and scope of the present disclosure, the integrated circuit devices 300 and 400 described with reference to FIGS. 7 and 8 and integrated circuit devices having various structures changed and modified therefrom may be fabricated. In some embodiments, to form the second buried insulating film 316 shown in FIG. 7 and the second buried insulating film 416 shown in FIG. 8, an etching atmosphere when removing a portion of the preliminary buried insulating film 116L may be controlled in the processes described with reference to FIG. 12. To form the insulating liner 414 and the gate dielectric film 452, which are shown in FIG. 8, a similar process to the process, which is described with reference to FIG. 22, of forming the insulating liner 214 and the gate dielectric film 252 may be performed.

While the present disclosure has been particularly shown and described with reference to embodiments thereof, it will be understood that various changes in form and details may be made therein without departing from the spirit and scope of the following claims.

What is claimed is:

1. An integrated circuit device comprising:
a pair of fin-type active regions that extend in a first direction and are on a substrate;
a gate line that is on the pair of fin-type active regions and extends in a second direction that intersects the first direction; and
a field insulating structure that is between the substrate and the gate line and at least partially overlaps a sidewall of each of the pair of fin-type active regions in the second direction,
wherein the field insulating structure comprises:
a first buried insulating film that contacts the sidewall of each of the pair of fin-type active regions;
an insulating liner that is between the pair of fin-type active regions and at least partially overlaps the first buried insulating film in a third direction that is perpendicular to the first direction and the second direction; and
a second buried insulating film that is between the pair of fin-type active regions and at least partially overlaps the insulating liner in the third direction,
wherein the second buried insulating film is spaced apart from the first buried insulating film in the third direction,
wherein the insulating liner is between the second buried insulating film and the first buried insulating film, and
wherein the second buried insulating film comprises a nitride film.

2. The integrated circuit device of claim 1, further comprising a gate dielectric film between the pair of fin-type active regions and the gate line, wherein:
the second buried insulating film of the field insulating structure is spaced apart from the pair of fin-type active regions in the second direction,
at least one of the insulating liner and the gate dielectric film is between the pair of fin type active regions and the second buried insulating film, and
the second buried insulating film of the field insulating structure has a first upper surface that contacts the gate dielectric film.

3. The integrated circuit device of claim 1, further comprising a gate dielectric film between the pair of fin-type active regions and the gate line, wherein:
the gate dielectric film comprises a protrusion that extends toward the substrate, and
the protrusion of the gate dielectric film contacts the sidewall of a first fin-type active region of the pair of fin-type active regions and is between the first fin-type active region and the second buried insulating film of the field insulating structure.

4. The integrated circuit device of claim 1, further comprising:
a pair of source/drain regions respectively on the pair of fin-type active regions; and
an inter-gate insulating structure that at least partially overlaps the pair of source/drain regions in the third direction,
wherein the field insulating structure is between the pair of source/drain regions, and
wherein the second buried insulating film of the field insulating structure has a second upper surface that contacts the inter-gate insulating structure.

5. The integrated circuit device of claim 1, further comprising:
a plurality of first insulating spacers that respectively at least partially overlap sidewalls of the gate line in the second direction;
a pair of source/drain regions respectively on the pair of fin-type active regions;
a plurality of second insulating spacers that are on the field insulating structure and respectively overlap sidewalls of the pair of source/drain regions in the second direction; and
an inter-gate insulating structure that at least partially overlaps the pair of source/drain regions and the plurality of second insulating spacers in the third direction,
wherein the field insulating structure is between the pair of source/drain regions,
wherein the plurality of first insulating spacers and the plurality of second insulating spacers comprise a same material, and
wherein the plurality of second insulating spacers and the inter-gate insulating structure contact an upper surface of the second buried insulating film of the field insulating structure.

6. The integrated circuit device of claim 1, further comprising a gate dielectric film that at least partially surrounds the gate line, wherein the second buried insulating film of the field insulating structure has an upper surface that contacts the gate dielectric film and has a concave shape relative to the gate line.

7. The integrated circuit device of claim 1, further comprising a gate dielectric film that at least partially surrounds the gate line, wherein the second buried insulating film of the field insulating structure has an upper surface that contacts the gate dielectric film and has a convex shape relative to the gate line.

8. The integrated circuit device of claim 1, wherein the second buried insulating film of the field insulating structure comprises a lower surface that has a convex shape relative to the substrate.

9. The integrated circuit device of claim 1, wherein:
each of the first buried insulating film and the insulating liner comprises a silicon oxide film, and
the second buried insulating film comprises a silicon nitride (SiN) film, a silicon oxynitride (SiON) film, a silicon oxycarbonitride (SiOCN) film, or a combination thereof.

10. The integrated circuit device of claim 1, wherein a thickness of the second buried insulating film in the third direction is greater than a thickness of the insulating liner in the third direction.

11. The integrated circuit device of claim 1, wherein:
a thickness of the second buried insulating film in the third direction gradually increases toward a center between the pair of fin-type active regions in the second direction,
the insulating liner of the field insulating structure that at least partially overlaps a lower surface of the second buried insulating film in the third direction and has a constant thickness in the third direction, and
the lower surface of the second buried insulating film faces the substrate.

12. An integrated circuit device comprising:
a fin-type active region that extends in a first direction and is on a substrate;
a nanosheet stack spaced apart from a fin top surface of the fin-type active region in a second direction that is perpendicular to the first direction, wherein the nanosheet stack faces the fin top surface and comprises at least one nanosheet that is separated from the substrate in the second direction by a first distance that is different from a second distance between the fin top surface and the substrate;
a gate line that is on the fin-type active region, at least partially surrounds the at least one nanosheet, and extends in a third direction that intersects the first direction; and
a field insulating structure that is between the substrate and the gate line and at least partially overlaps a sidewall of the fin-type active region in the third direction,
wherein the field insulating structure comprises:
a first buried insulating film that contacts the sidewall of the fin-type active region;
an insulating liner that at least partially overlaps an upper surface of the first buried insulating film in the second direction; and
a second buried insulating film that at least partially overlaps the insulating liner in the second direction, is spaced apart from the first buried insulating film in the second direction,
wherein the insulating liner is between the second buried insulating film and the first buried insulating film, and
wherein the second buried insulating film comprises a nitride film.

13. The integrated circuit device of claim 12, wherein, a distance between a first portion of the second buried insulating film and the substrate in the second direction is less than a distance between a second portion of a lowermost nanosheet of the at least one nanosheet and the substrate in the second direction.

14. The integrated circuit device of claim 12, further comprising a gate dielectric film that is between the fin-type active region and the at least one nanosheet and at least partially surrounds the gate line, wherein:
the second buried insulating film of the field insulating structure is spaced apart from the fin-type active region in the third direction,
at least one of the insulating liner and the gate dielectric film is between the second buried insulating film and the fin-type active region, and
the second buried insulating film of the field insulating structure has an upper surface that contacts the gate dielectric film.

15. The integrated circuit device of claim 12, further comprising a gate dielectric film that is between the fin-type active region and the at least one nanosheet and at least partially surrounds the gate line, wherein:
the gate dielectric film comprises a protrusion that is between the second buried insulating film of the field insulating structure and the fin-type active region and extends toward the substrate, and
a first distance between the substrate and a first lowermost surface of the second buried insulating film in the second direction is less than a second distance between the substrate and a second lowermost surface of the protrusion of the gate dielectric film.

16. The integrated circuit device of claim 12, wherein:
the second buried insulating film of the field insulating structure is spaced apart from the fin-type active region in the third direction, and
in the third direction, a first distance between the insulating liner and the fin-type active region is less than a second distance between the insulating liner and the second buried insulating film.

17. The integrated circuit device of claim 12, wherein each of the insulating liner and the second buried insulating film is spaced apart from the fin-type active region in the third direction.

18. The integrated circuit device of claim 12, further comprising:
a source/drain region on the fin-type active region;
an insulating spacer that is on the field insulating structure and that at least partially overlaps a sidewall of the source/drain region in the third direction; and
an inter-gate insulating structure that at least partially overlaps the source/drain region and the insulating spacer in the second direction,
wherein the field insulating structure is adjacent to the source/drain region in the third direction, and
each of the insulating spacer and the inter-gate insulating structure contacts an upper surface of the second buried insulating film of the field insulating structure.

19. The integrated circuit device of claim 12, wherein:
the first buried insulating film comprises a first silicon oxide film having a first density,
the insulating liner comprises a second silicon oxide film having a second density that is different from the first density of the first silicon oxide film,
the second buried insulating film comprises a silicon nitride (SiN) film, a silicon oxynitride (SiON) film, a silicon oxycarbonitride (SiOCN) film, or a combination thereof, and
a thickness of the second buried insulating film in the second direction is greater than a thickness of the insulating liner in the second direction.

20. An integrated circuit device comprising:
a pair of fin-type active regions that extend in a first direction and are on a substrate;
a pair of nanosheet stacks that are respectively on the pair of fin-type active regions and each comprise at least one nanosheet;
a gate line that is on the pair of fin-type active regions, at least partially surrounds the at least one nanosheet of each of the pair of nanosheet stacks, and extends in a second direction that intersects the first direction;
a pair of source/drain regions respectively on the pair of fin-type active regions; and
a field insulating structure that is between the pair of fin-type active regions and comprises a first portion between the substrate and the gate line and a second portion between the pair of source/drain regions,
wherein the field insulating structure comprises:
a first buried insulating film that contacts a sidewall of each of the pair of fin-type active regions;
an insulating liner that at least partially overlaps an upper surface of the first buried insulating film in a third direction by a constant thickness, wherein the third direction is perpendicular to the first direction and the second direction; and
a second buried insulating film that at least partially overlaps the insulating liner and is spaced apart from the first buried insulating film in the third direction,
wherein the insulating liner is between the first buried insulating film and the second buried insulating film,
wherein the second buried insulating film comprises a varying thickness in the third direction and the second direction,
wherein the first buried insulating film and the insulating liner respectively comprise silicon oxide films having different densities, and
wherein the second buried insulating film of the field insulating structure comprises a silicon nitride (SiN) film, a silicon oxynitride (SiON) film, a silicon oxycarbonitride (SiOCN) film, or a combination thereof.
